(19) United States
(12) Patent Application Publication
(10) Pub. No.: US 2012/0193737 A1
(43) Pub. Date: Aug. 2, 2012

(54) MRAM DEVICE AND METHOD OF ASSEMBLING SAME

(75) Inventors: Xingshou Pang, Tianjin (CN); Sheila F. Chopin, Round Rock, TX (US); Jun Li, Tianjin (CN); Xuesong Xu, Tianjin (CN)

(73) Assignee: FREESCALE SEMICONDUCTOR, INC, Austin, TX (US)

(21) Appl. No.: 13/333,996

(22) Filed: Dec. 21, 2011

(30) Foreign Application Priority Data
Feb. 1, 2011 (CN) 201110062115.X

(51) Int. Cl. H01L 29/82; H01L 43/12

(52) U.S. Cl. 257/421; 438/3; 438/107; 257/659; 257/E43.006; 257/E29.323

(57) ABSTRACT

A method of packaging a magnetoresistive random access memory (MRAM) die includes providing a lead frame having a die pad and lead fingers. The MRAM die is attached to the die pad with a first die attach adhesive and bond pads of the MRAM die are electrically connected to the lead fingers of the lead frame with wires using a wire bonding process. A pre-formed composite magnetic shield is attached to a top surface of the MRAM die with a second die attach adhesive. The magnetic shield includes a magnetic permeable filler material dispersed within an organic matrix. An encapsulating material is dispensed onto a top surface of the lead frame, MRAM die and magnetic shield such that the encapsulating material covers the MRAM die and the magnetic shield. The encapsulating material is then cured.

### BACKGROUND OF THE INVENTION

The present invention relates generally to semiconductor device packages, and more particularly to magnetic shielded semiconductor device packages.

Magnetic materials are used in a variety of semiconductor devices such as magnetic cell memories and magnetic field sensors. Magnetic random access memory (MRAM) devices are being explored as non-volatile solid state memory devices for embedded and stand alone applications. Typically MRAM devices utilize magnetic material within memory cells to store data bits.

MRAM devices may be subject to error in the presence of stray or externally applied electromagnetic fields other than applied write fields. Such stray fields can originate from a variety of sources including electronic devices such as computers, displays, etc. and may have sufficient magnitude to switch the logic state of one or more memory cells even in the absence of a write field.

One way of protecting the MRAM devices from the external environment is by encapsulation with an epoxy material or transfer molding a thermoplastic resin around the device. However, the epoxy or plastic encapsulent does not provide effective shielding from radiation such as EMI or RFI.

Some conventional shielding systems use a conductive metallic shield that is attached to an outside surface of the package. However, the processing of a metallic shield is difficult and the metallic shield is typically not compatible with other packaging materials such as molding compounds and die attach epoxy employed in such packages thereby causing delamination and reliability issues. Moreover, the metallic shield adds to the overall size of the package and is substantially expensive, thereby making the overall packaging costs unattractive.

Other systems use magnetic foils to shield the device from magnetic fields. However, use of magnetic foils gives rise to serious interface delamination issues particularly when double foils are used in a cladding structure.

Therefore a need exists for a cost effective magnetic shielding process that can be used in a variety of semiconductor devices.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 is a cross-sectional view of a semiconductor device in accordance with one embodiment of the present invention;

FIG. 2 illustrates a step of attaching a semiconductor die to a lead frame;

FIG. 3 illustrates a step of electrically connecting the semiconductor die to the lead frame;

FIG. 4 illustrates a step of attaching a pre-formed magnetic shield to the semiconductor die;

FIG. 5 illustrates a step of dispensing an encapsulating material onto the lead frame, die and the magnetic shield;

FIG. 6 illustrates a step of curing the encapsulating material dispensed on the lead frame; and

FIG. 7 illustrates a step of separating the array of packaged semiconductor devices into individual packaged semiconductor devices.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention provides a method of packaging a magnetoresistive random access memory (MRAM) die. The method includes providing a lead frame having a die pad and lead fingers. The MRAM die is attached to the die pad with a first die attach adhesive and bond pads of the MRAM die are electrically connected to the lead fingers of the lead frame with wires using a wire bonding process. A pre-formed composite magnetic shield is attached to a top surface of the MRAM die with a second die attach adhesive. The magnetic shield includes a magnetic permeable filler material dispersed within an organic matrix. An encapsulating material is dispensed onto a top surface of the lead frame, MRAM die and magnetic shield such that the encapsulating material covers the MRAM die and the magnetic shield. The encapsulating material is then cured.

In another embodiment, the present invention is a MMRAM device assembled in accordance with the above-described method.

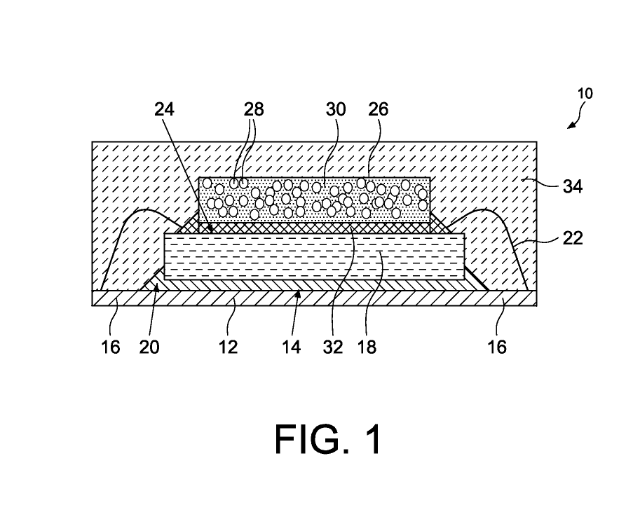

Referring now to FIG. 1, a cross-sectional view of a semiconductor device 10 is shown. The semiconductor device 10 includes a lead frame 12 with a die pad 14 and lead fingers 16. The lead frame 12 may include a Bismaleimide Triazine (BT) substrate that is suitable for Ball Grid Array (BGA) products. Alternatively, the lead frame 12 may be formed of copper, an alloy of copper, a copper plated iron/nickel alloy, plated aluminum, or the like.

A semiconductor die 18 is attached to the die pad 14 and is electrically coupled to the lead fingers 16. In this exemplary embodiment of the invention, the semiconductor die 18 includes a magnetoresistive random access memory (MRAM) die. The MRAM die 18 may be attached to the lead frame 12 using a first die attach adhesive 20. The MRAM die 18 and the lead frame 12 are well known components and thus detailed descriptions and possible alternative embodiments thereof are not necessary for a complete understanding of the present invention.

In this exemplary embodiment of the invention, the MRAM die 18 is attached and electrically coupled to the lead fingers 16 of the lead frame 12 with wires 22. The wires 22 are bonded to pads on an active surface 24 of the MRAM die 18 and to corresponding contact pads on the lead frame 12 using a well known wire bonding process and known wire bonding equipment. The wires 22 are formed from a conductive material such as aluminium or gold.

Another way of electrically connecting the MRAM die 18 to the lead frame 12 is to connect bond pads of the MRAM die 18 to the lead fingers 16 with flip-chip bumps (not shown) attached to an underside of the MRAM die 18. The flip-chip bumps may include solder bumps, gold balls, molded studs, or combinations thereof.

A magnetic shield 26 is attached to the top surface 24 of the MRAM die 18. In this exemplary embodiment of the invention, the magnetic shield 26 includes a composite material formed of a magnetic permeable filler material 28 dispersed within a base matrix 30. The magnetic permeable filler material 28 includes metal particles configured to provide electromagnetic shielding for the MRAM die 18. For example, the magnetic permeable filler material 28 may include nickel (Ni), NiFe and NiFeMo, among other suitable materials. Such magnetic permeable filler materials are commercially available from metal supply companies, such as Carpenter Technology Corporation of Wyomissing, Pa.

In this exemplary embodiment of the invention, the base matrix 30 includes at least one of an organic compound and a metal. The base matrix 30 preferably comprises composites of organic resins such as epoxy resin, acrylic resin, polyester resin, and polycarbonate and a permeable metal filler such as Ni, NiFe, and NiFeMo. The filler content should be from 20% wt to 80% wt and the thickness of shield should be from 100 um to 500 um depending on the overall package thickness and shielding efficiency requirements. The magnetic shield 26 is attached to the MRAM die 18 using a second die attach adhesive 32. The first and second die attach adhesives 20 and 32 include epoxy. However, other suitable materials may be utilized for the die attach adhesives.

An encapsulating material 34 covers the lead frame 12, the MRAM die 18 and the magnetic shield 26. The encapsulating material 34 may include an epoxy molding compound, as is known in the art.

As will be appreciated by one skilled in the art, the magnetic shield 26 formed of magnetically permeable metal powder 28 dispersed in the organic material 30 is compatible with other package materials such as the molding compound 34 and the die attach adhesive 32 thereby providing substantially reliable packaged configuration. Moreover, composition of the composite shield 26 is selected to meet a desired magnetic shielding requirement.

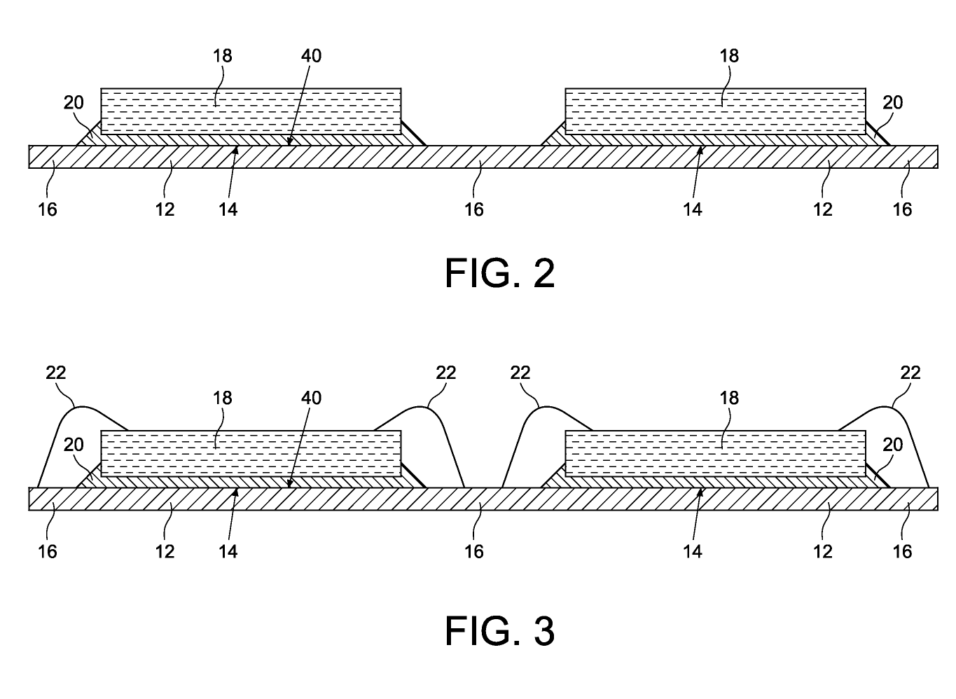

FIGS. 2-7 illustrate a method of forming the semiconductor device 10 of FIG. 1. FIG. 2 is an illustration of a step of attaching the semiconductor die 18 to a top surface 40 of the lead frame 12. In this exemplary embodiment of the present invention, the semiconductor die 18 includes a MRAM die. As illustrated, the lead frame 12 includes the die pad 14 and the lead fingers 16. A wafer may be processed to form the lead frame 12 with the die pad 14 and the lead fingers 16 by wafer mounting and wafer sawing processes, as are known in the art. Alternatively, a wafer/panel can be purchased as a patterned leadframe with die pads and lead fingers already formed in a desired pattern.

Although only two device portions are illustrated in FIG. 2, many more device portions may exist. In the embodiment shown, each of the device portions has the same structure for simplicity of manufacturing.

The MRAM die 18 is attached to the die pad 14 of the lead frame 12 with the first die attach adhesive 20 such as die-bonding epoxy. The MRAM die 18 may be placed on the die attach adhesive 20 using a pick and place tool and the adhesive 20 is subsequently cured as is known in the art.

FIG. 3 shows the step of electrically connecting the MRAM die 18 to the lead frame 12. In this exemplary embodiment of the invention, bond pads of the MRAM die 18 are electrically connected to the lead fingers 16 of the lead frame 12 with the wires 22 using a well known wire bonding process and known wire bonding equipment.

Another way of connecting the MRAM die 18 is through flip-chip bumps (not shown) attached to an underside of the MRAM 18. The flip-chip bumps may include solder bumps, gold balls, molded studs, or combinations thereof. The bumps may be formed or placed on the MRAM die 18 using known techniques such as evaporation, electroplating, printing, jetting, stud bumping and direct placement. The MRAM die 18 is flipped and the bumps are aligned with contact pads (not shown) of the lead fingers 16.

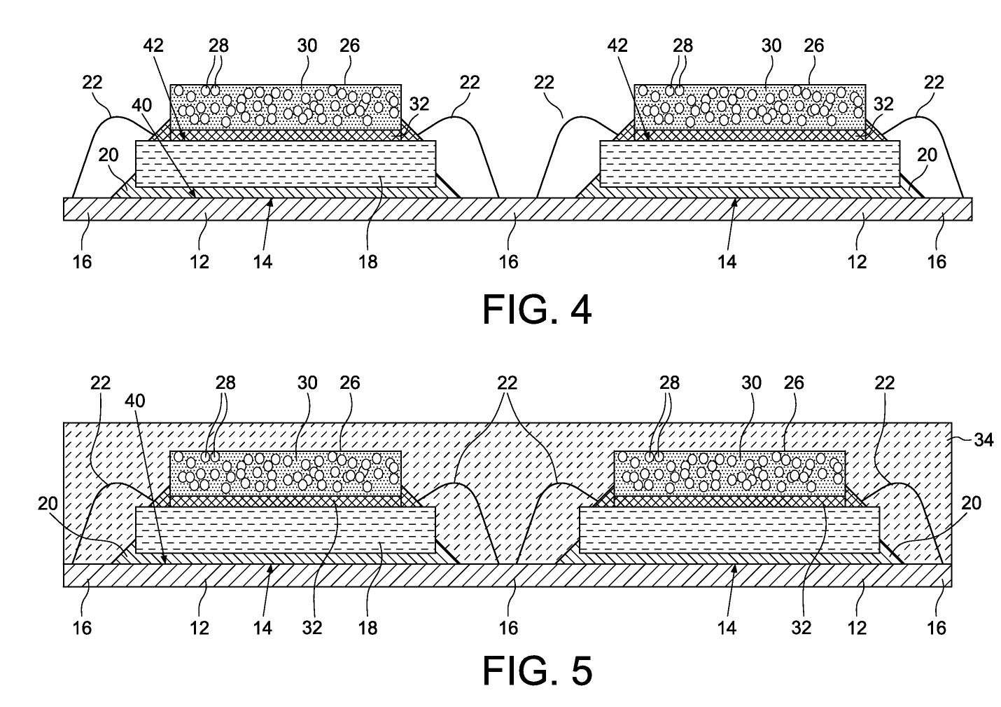

FIG. 4 shows the step of attaching a pre-formed magnetic shield 26 to a top surface 42 of the MRAM die 18. In this exemplary embodiment of the invention, the magnetic shield 26 is formed of the magnetic permeable filler material 28 embedded in the base matrix 30. The base matrix 30 includes at least one of an organic compound and a metal. Moreover, the magnetic permeable filler material 28 includes metal particles.

As will be appreciated by one skilled in the art, the composite metal shield 26 may be formed using known composite forming techniques. The pre-formed composite metal shield 26 is attached to the MRAM die 18 with the die attach adhesive 32 such as epoxy.

FIG. 5 shows the step of dispensing an encapsulating material 34 such as epoxy onto the top surface 40 of the lead frame 12. The encapsulating material 34 covers the die 18 the magnetic shield 26. The encapsulating material 34 may be dispensed with a nozzle of a conventional dispensing machine, as is known in the art.

Alternatively, the encapsulating material 34 may include a silica-filled resin, a ceramic, a halide-free material, the like, or combinations of the above. The encapsulating material is typically applied using a liquid, which is then heated to form a solid by curing in a UV or ambient atmosphere. The encapsulating material 34 can also be a solid that is heated to form a liquid and then cooled to form a solid mold. Any other encapsulating process may be used.

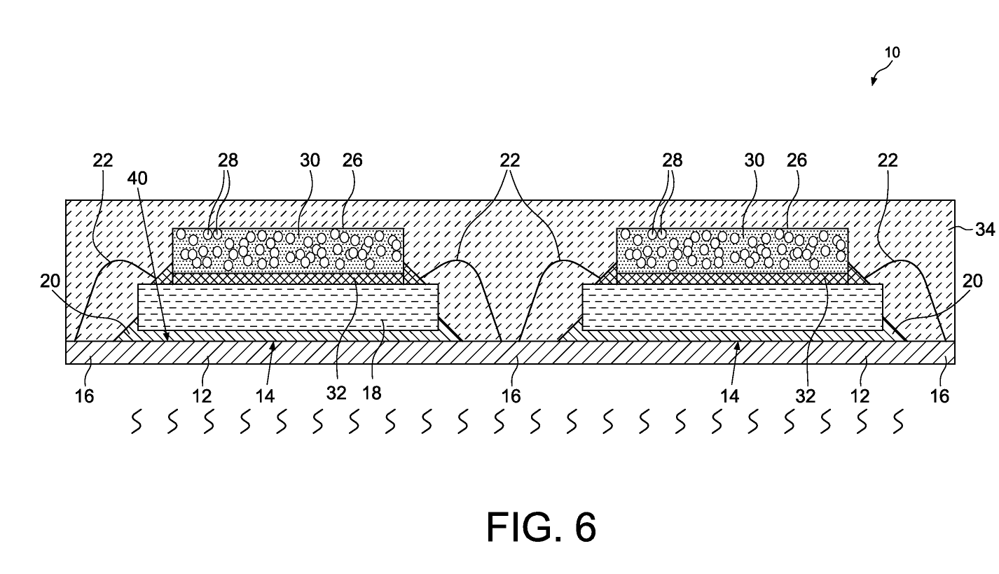

Subsequently, the encapsulating material 34 and the die attach adhesives 20 and 32 are cured in an oven, as shown in FIG. 6 to form an array of semiconductor devices.

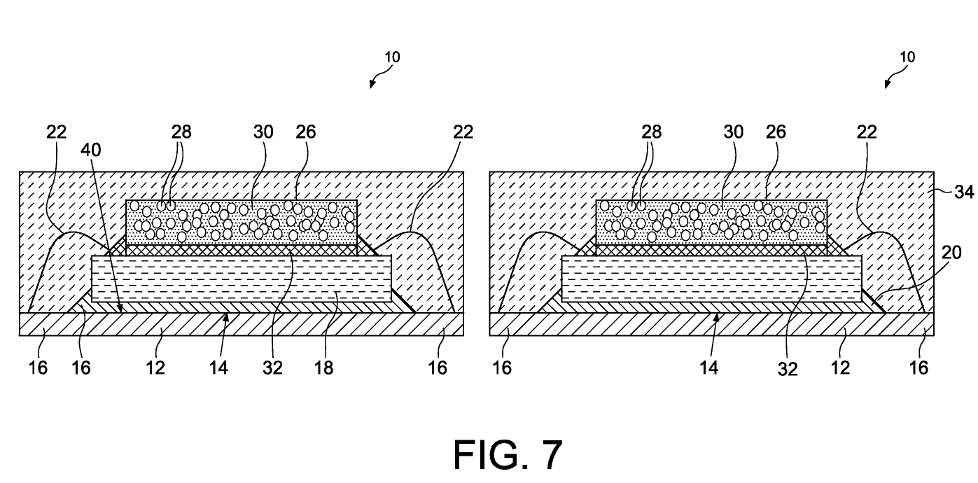

FIG. 7 shows individual semiconductor devices 10 being separated from each other by a singulation process. Singulation processes are well known and may include cutting with a saw or a laser.

The present invention, as described above, allows for packaging a MRAM die. A pre-formed composite magnetic shield formed of metal particles embedded in an organic material is attached to the MRAM die using a die attach adhesive. The magnetic shield described above has good shielding property with a shielding efficiency in a range of about 15 dB to about 50 dB. Moreover, the magnetic shield has substantially lower weight as compared to the conventional metal shields.

Thus, the present invention provides a method of packaging a MRAM die that utilizes a pre-formed composite magnetic shield, which is compatible with other organic packaging materials while reducing manufacturing costs for such devices. The magnetic shield described above utilizes commercially available metal powder such as Ni, NiFe and NiFeMo that provide the desired magnetic shielding efficiency and is laid on and attached to the die using known die attachment techniques and equipment.

By now it should be appreciated that there has been provided an improved MRAM device and a method of assembling the MRAM device. Circuit details are not disclosed because knowledge thereof is not required for a complete understanding of the invention. Although the invention has been described using relative terms such as “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A method of packaging a semiconductor die, comprising the steps of:
providing a lead frame having a die pad and lead fingers;
attaching a semiconductor die to the die pad;
electrically connecting bond pads of the semiconductor die to the lead fingers of the lead frame;
attaching a pre-formed magnetic shield to a top surface of the semiconductor die, wherein the magnetic shield is formed of a magnetic permeable filler material embedded in a base matrix; and
dispensing an encapsulating material onto a top surface of the lead frame, die and shield such that the encapsulating material covers the die and the shield.

2. The method of packaging a semiconductor die of claim 1, wherein the base matrix comprises at least one of an organic compound and a metal.

3. The method of packaging a semiconductor die of claim 1, wherein the magnetic permeable filler material comprises nickel (Ni).

4. The method of packaging a semiconductor die of claim 1, wherein the magnetic permeable filler material comprises NiFe.

5. The method of packaging a semiconductor die of claim 1, wherein the magnetic permeable filler material comprises NiFeMo.

6. The method of packaging a semiconductor die of claim 1, wherein the electrically connecting step comprises connecting the bond pads of the semiconductor die to the lead fingers of the lead frame with wires using a wire bonding process.

7. The method of packaging a semiconductor die of claim 1, wherein the electrically connecting step comprises directly connecting the bond pads of the semiconductor die to the lead fingers with flip-chip bumps.

8. The method of packaging a semiconductor die of claim 1, wherein the encapsulating material comprises epoxy.

9. The method of packaging a semiconductor die of claim 1, wherein the semiconductor die comprises a magnetoresistive random access memory (MRAM) device.

10. A semiconductor device packaged in accordance with the method of claim 1.

11. A semiconductor device, comprising:
a lead frame with a die pad and lead fingers;
a semiconductor die attached to the die pad and electrically coupled to the lead fingers;
a magnetic shield attached to a top surface of the semiconductor die, wherein the magnetic shield comprises a composite material formed a magnetic permeable filler material dispersed within an organic matrix; and
an encapsulating material covering the lead frame, the semiconductor die and the magnetic shield.

12. The semiconductor device of claim 11, wherein the semiconductor die comprises a magnetoresistive random access memory (MRAM) die.

13. The semiconductor device of claim 11, wherein the magnetic permeable filler material comprises metal particles configured to provide electromagnetic shielding for the semiconductor die.

14. The semiconductor device of claim 11, wherein the encapsulating material comprises epoxy.

15. The semiconductor device of claim 11, wherein the semiconductor die is electrically coupled to the lead frame via bond wires.

16. The semiconductor device of claim 11, wherein the semiconductor die is electrically coupled to the lead frame via a plurality of electrically conductive bumps.

17. A method of packaging a magnetoresistive random access memory (MRAM) die, comprising the steps of:
providing a lead frame having a die pad and lead fingers;
attaching the MRAM die to the die pad with a first die attach adhesive;
electrically connecting bond pads of the MRAM die to the lead fingers of the lead frame with wires using a wire bonding process;
attaching a pre-formed composite magnetic shield to a top surface of the MRAM die with a second die attach adhesive, wherein the magnetic shield comprises a magnetic permeable filler material dispersed within an organic matrix;
dispensing an encapsulating material onto a top surface of the lead frame, MRAM die and magnetic shield such that the encapsulating material covers the MRAM die and the magnetic shield; and
curing the encapsulating material.

18. The method of packaging a semiconductor die of claim 17, further comprising forming a plurality of semiconductor packages on a common substrate, and wherein following the curing step, the plurality of semiconductor packages are singulated to form individual semiconductor packages.

19. The method of packaging a semiconductor die of claim 17, wherein the first and second die attach adhesives comprise epoxy.

20. The method of packaging a semiconductor die of claim 17, wherein the magnetic filler material comprises metal particles.
